(19) United States
(12) Patent Application Publication
(10) Pub. No.: US 2026/0147030 A1
(43) Pub. Date: May 28, 2026

(54) METHOD FOR MEASURING AND PROCESSING OF THERMOGRAPHY DATA

(71) Applicants: UNIVERSITE DE RENNES, RENNES (FR); CENTRE NATIONAL DE LA RECHERCHE SCIENTIFIQUE, PARIS (FR); INSTITUT NATIONAL DES SCIENCES APPLIQUEES DE RENNES, RENNES CÉDEX 7 (FR); NANTES UNIVERSITÉ, NANTES (FR); CENTRALESUPELEC, GIF-SUR-YVETTE (FR)

(72) Inventors: Artem BORYSKIN, THORIGNE FOUILLARD (FR); Massinissa ZIANE, RENNES (FR); Ronan SAULEAU, ACIGNE (FR); Maxim ZHADOBOV, RENNES (FR)

(21) Appl. No.: 19/119,920

(22) PCT Filed: Oct. 9, 2023
(86) PCT No.: PCT/EP2023/077888

§ 371 Date: Apr. 10, 2025

(30) Foreign Application Priority Data
Oct. 13, 2022 (EP) 22306552.5

(51) Int. Cl. G01R 29/08

(52) U.S. Cl. CPC G01R 29/0814; G01R 29/0892

(57) ABSTRACT

A method for retrieving a useful signal from a bulk response signal emitted by a target subjected to an excitation signal, including:
providing a first excitation signal at least modulated at a frequency F_{lock} during a first period of time corresponding to a transient mode of a response signal and causing a first bulk response signal and recording the first bulk response signal;
calculating a first Fourier transform of the bulk response signal in response to the first excitation signal during the first period to provide a first spectrum of an exponential term a first spectrum of ambient noise and a first spectrum of a useful signal in the first measured bulk response signal; and
extracting the first spectrum of a useful signal through removing the first spectrum of the exponential term from the first Fourier transform.

### CROSS REFERENCE TO RELATED APPLICATIONS

This application is a National Stage of International Application No. PCT/EP2023/077888, having an International Filing Date of 9 Oct. 2023, which designated the United States of America, and which International Application was published under PCT Article 21(2) as WO Publication No. 2024/079044, which claims priority from and the benefit of European Patent Application No. 22306552.5 filed on 13 Oct. 2022, the disclosures of which are incorporated herein by reference in their entireties.

### BACKGROUND

### Field

The present disclosure relates to methods for processing thermography data and, more specifically thermography data resulting from exposure of a target with a low power electromagnetic source for instance in metrology or dosimetry or quality control measurements.

### Brief Description of Related Developments

When analysing signals of small amplitudes that are buried in noise and other signal disturbances with amplitudes that might be comparable or even higher than the signal of interest itself, a post-processing technique, known as “lock-in”, can be used. Its basic principle consists in modulating the excitation signal with time period Tlock and with a specific waveform, such as sine, square, etc. Its implementation requires modulated excitation with a predetermined waveform and periodicity. The Fourier theory can be used to transform the measured signals from the time domain to the spectral domain and then to remove the noise spectral components from the measured spectrum thus filtering the useful spectral component of the periodic excitation at the lock-in frequency.

To be efficient, the lock-in technique is usually applied in the steady state (or at least quasi steady state) mode because in this case the spectrum of the continuous component of the signal is localized near zero frequency, facilitating the efficient filtering. The “position” of the lock-in spectral component in the frequency domain can be tuned on demand by varying the lock-in frequency.

However, in many real-life scenarios the steady state can only be achieved after a long period of time, typically tens of minutes and up to several hours, which can be prohibitively long for certain applications because it restricts the throughput of the entire production/characterization cycle.

In particular, this is often the case for multi-physics problems that involve energy transformation from one form to another, such as, for example, electromagnetic to thermal energy conversion. The latter is often associated with the relatively high thermal noise level and long delay needed to reach the steady state equilibrium because of the thermal conductivity of all the materials and host medium. In this case, long acquisition time may also suffer from the environmental temperature drift and undesired heat spread.

A specific practical example of a device that can suffer from the aforementioned problem is an electromagnetic (hereafter EM) waves measurement system where the EM metrics are retrieved from temperature dynamics measurements. Such systems are often used for characterization of antennas and wireless devices.

More specifically, such systems rely on using thermal sensors, e.g., infrared imaging sensors, for measuring heat patterns induced by absorbed EM energy in a screen, such as a thin lossy dielectric film, exposed to the EM radiation emitted by a wireless device under test. In case of portable wireless devices, such as smartphones or tablets, operating at the maximum power, typically ranging from tens to hundreds of mW, the corresponding temperature rise in the 0.1 to 1° C. range may be induced after a short exposure, e.g., shorter than several minutes. Such temperature rise may be comparable with fluctuations of the ambient temperature representing the noise level. The traditional ways to overcome this problem comprise:
Increasing the exposure time and therefore the useful signal level: Indeed, a larger temperature rise, e.g., above 1° C., can be reached after a longer exposure duration, e.g., above several minutes. However, longer exposure provokes another important problem related to the heat spread in the plane of the screen that disturbs the heat pattern, mainly in enlarging the heated zone and smoothening the pick values, thus resulting in a poor correlation between the measured heat pattern and the initial EM field distribution representing the heat source.
Applying a lock-in method with a modulated excitation and noise filtering in the Fourier domain in steady state condition, whose achievement may require even longer period of time, up to several hours.

It shall also be noted that measurement procedures in metrology often require repeated tests, considering different antenna configurations and/or relative position of the wireless device with respect to the target. The time needed to reach the steady state in heating and then in cooling before starting a new test becomes prohibitively long.

In consequence, there is always a trade-off between the exposure and signal acquisition duration, signal level, accuracy and signal to noise ratio (SNR) of the postprocessing procedure that is affected by the heat spread phenomenon.

In view of the above problems, there is a strong need for methods that would allow fast and reliable measurements of low-amplitude signals in the transient mode e.g., without waiting for reaching a steady state.

### SUMMARY

An important feature of the present disclosure consists in achieving measurements on a target using the lock-in technique during an initial transient phase of a signal in response to an excitation signal received by the target.

More particularly, the present disclosure concerns a method for retrieving a useful signal from a bulk response signal emitted by a target subjected to an excitation signal, comprising:
a.—providing a first excitation signal at least modulated at a frequency F_{lock} during a first period of time corresponding to a transient mode of a response signal and causing a first bulk response signal and recording said first bulk response signal,
b.—calculating a first Fourier transform FT{ΔT(t)} of said bulk response signal in response to said first excitation signal during said first period to provide a first spectrum of an exponential term (fₑ(ω)) a first spectrum of ambient noise (fₙ(ω)) and a first spectrum of a useful signal (fₚ(ω)) in said first measured bulk response signal,
c.—extracting said first spectrum of a useful signal (fₚ(ω)) through removing said first spectrum of the exponential term (fₑ(ω)) from said first Fourier transform.

In a first aspect, said first excitation signal may be followed with a further signal in a second period of time, and said method may comprise further:
a.—providing said second period of time with a first sub-period of time where said further signal comprises a null excitation signal value to let said bulk response signal end and a second sub period of time where said further signal comprises a constant power excitation signal having a power value equal to the mean power of said first signal during said first period,
b.—calculating a second Fourier transform FT{ΔT(t)} of a second measured bulk response signal in response to said constant power excitation signal in said second sub-period to provide a second spectrum of said exponential term (fₑ(ω)), in said second measured bulk response signal,
c.—subtracting said second spectrum of said exponential term (fₑ(ω)) from said first spectrum of said exponential term (fₑ(ω)) in said first Fourier transform FT{ΔT(t)} for removing said first spectrum of the exponential term (fₑ(ω)) from said first Fourier transform and extracting the first spectrum of the useful signal (fₚ(ω)).

In a second aspect, the method may comprise further:
a.—modulating said first excitation signal with a non-periodic envelope during said first period of time wherein said non-periodic envelope comprises a positive skew distribution during said first period of time, said positive skew distribution being adapted to have said bulk signal comprising a non-periodic Gaussian-like shape in order that said first spectrum of said exponential term (fₑ(ω)) does not overlap said third spectrum of said useful signal (fₚ(ω)),
b. and
c.—filtering said first spectrum of said exponential term (fₑ(ω)) in said first Fourier transform for removing said first spectrum of the exponential term (fₑ(ω)) from said first Fourier transform and extracting the first spectrum of the useful signal (fₚ(ω)).

In a third aspect the method may comprise:
a.—reconstructing by interpolation of a non-periodic part of the bulk response signal after provision of said first excitation signal power modulated at a frequency F_{lock} during a first period of time corresponding to a transient mode of said bulk response signal,
b.—calculating a third Fourier transform FT{ΔT(t)} of said non-periodic part to provide a third spectrum of an exponential term (fₑ(ω)),
c.—subtracting said third spectrum of said exponential term (fₑ(ω)) from said first spectrum of said exponential term (fₑ(ω)), said spectrum of a useful signal (fₚ(ω)) in said first Fourier transform FT{ΔT(t)} for removing said first spectrum of the exponential term (fₑ(ω)) from said first Fourier transform and extracting the first spectrum of the useful signal (fₚ(ω)).

The method may comprise an inverse Fourier transform to provide said useful signal (fₚ(ω)) after extracting the first spectrum of the useful signal (fₚ(ω)).

The method may further comprise a retrieval of a quantitative characteristic of the EM field incident on or absorbed by the target based on said useful signal and said first excitation signal.

The excitation signal may be one of electromagnetic waves such as microwave, mm-wave, IR, visible, or UV light generated by an electromagnetic source such as a wireless communication device, an EM power generator, a lamp, a laser or a heater or their combination.

Said excitation signal may also be a heat wave generated by a heat source driven by an electrical or mechanical force.

The bulk response signal may be a time-variable physical quantity relative to the heat generated by a medium of the target when exposed to said excitation signal such as:
a.—an intensity of an IR radiation generated by said medium in response to said excitation signal, or
b.—an amplitude and/or frequency variation of an emitted or reflected light by a material of the target such as a thermosensitive material, such as liquid crystal or a phase change material including chalcogenide glass or vanadium dioxide in response to said excitation signal; or
c.—a voltage generated by a thermocouple attached or embedded in said medium of the target.

Emission of said excitation signal is preferably stopped before a thermal steady state condition (SS) of the target is reached.

The method preferably comprises filtering the ambient noise (fₙ(ω)) in the time or frequency domain to suppress the ambient noise from the useful signal (fₚ(ω)).

The present disclosure also concerns a system for performing the method of the disclosure, such system comprising a source of excitation signal, in said source means to modulate a power of said excitation signal at a frequency F_{lock}, a target providing a bulk response signal when subjected to said excitation signal, sensor means for acquiring said bulk response signal, analog to digital conversion means and computer means configured to process said recording, reconstructing, calculating and subtracting on digital data representative of bulk response signals converted by said analog to digital conversion means.

Said source may comprise means to modulate a power of said excitation signal with a periodic or non-periodic envelope.

Said target may have a 3D structure comprising at least one layer of a lossy dielectric medium made of an organic or inorganic insulating material or semiconductor material. In this regard, lossy is in the sense that this medium can actually absorb the EM radiation at the frequency of the excitation signal. This ability for EM field absorption is quantitively defined by the value of the imaginary part of the complex dielectric permittivity. Alternatively, I can be defined by the loss tangent (i.e. ratio of the imaginary and real parts of the complex dielectric permittivity).

The source of excitation signal may be a wireless communication device and the target may be a test object subject to EM radiation of said wireless communication device, said sensor is an IR sensor measuring intensity of the IR radiation, which is proportional to the temperature of the object being a source of this IR radiation.

The system may further comprise communication means between said source of excitation signal and said computer means for scheduling emission of said excitation signal and acquiring said bulk response signal.

### BRIEF DESCRIPTION OF THE DRAWINGS

A detailed description of exemplary aspects of the disclosure will be discussed hereunder in reference to the attached drawings where:

FIG. 1A shows a typical heat dynamics at a surface of an object made of a lossy dielectric exposed to non-ionizing electromagnetic radiation under exposure with a constant in time incident power density;

FIG. 1B shows typical heat dynamics at a surface of an object made of a lossy dielectric exposed to non-ionizing electromagnetic radiation modulated by a temporal sequence of periodic pulses;

FIG. 1C shows representation of Fourier spectrum of temperature rise dynamics in a transient regime TR part of FIG. 1B;

FIG. 1D shows representation of Fourier spectrum of temperature rise dynamics in a steady state regime SS part of FIG. 1B;

FIG. 1E shows a curve of an extracted useful signal from a bulk response signal;

FIG. 2 shows a power modulated excitation signal curve according to a first aspect of the present disclosure;

FIG. 3A shows the temperature elevation resulting from the signal curve of FIG. 2;

FIG. 3B shows the spectrums in a first part and third part of FIG. 2 and a resulting spectrum curve after subtraction;

FIG. 4A shows a power modulated excitation signal curve according to a second aspect of the present disclosure;

FIG. 4B shows a decomposition of the curve of FIG. 4B;

FIG. 5A shows a resulting bulk response signal from the power curve of FIG. 4;

FIG. 5B shows the spectrum of the curve of FIG. 5A;

FIG. 6A shows an excitation signal that consist of a periodic ON/OFF signal and non-periodic signal and resulting bulk response signal curve used in a third aspect;

FIG. 6B shows the resulting curve with interpolated non-periodic component extracted from the bulk response signal curve of FIG. 6A;

FIG. 7 shows a reconstruction of a spectrum of a useful signal in the third aspect.

FIG. 8 shows a schematic perspective view of a first example of a system in accordance with the present disclosure;

FIG. 9 shows a schematic perspective view of a second example of a system in accordance with the present disclosure.

### DETAILED DESCRIPTION

In the following, the proposed method is illustrated referring to an example of practical application in EM measurements, where it can be beneficially used for post-processing of heat patterns induced by EM field radiated by low-power wireless devices. However, it is to be understood that the proposed method of transient lock-in is not limited to this application and can be applied for post-processing of any analytical or experimental data related to a thermo-dynamic system with a heat source represented by an EM loss (without limitations on the frequency range, which can be for example low frequency, microwave, mmWave, THz or optical) or any other heat source (e.g., electrical, magnetic, mechanical).

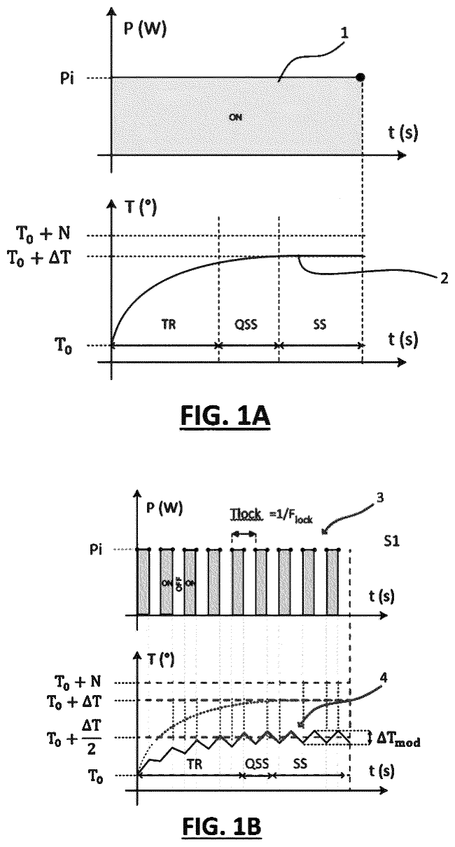

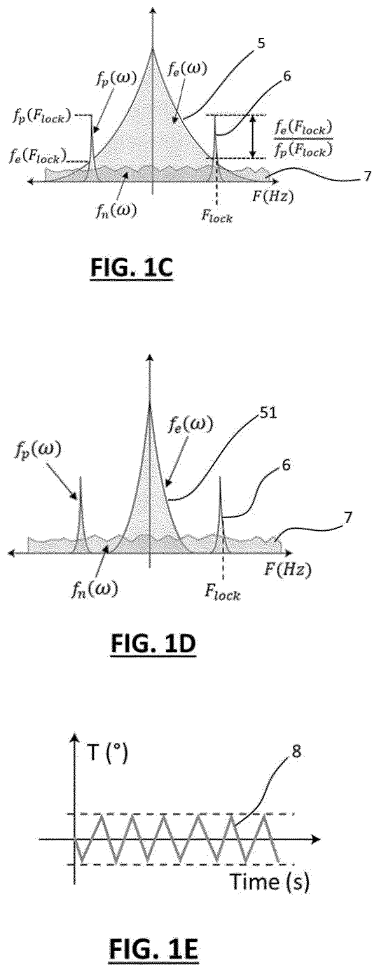

FIG. 1A illustrates typical heat dynamics 2 of an object exposed to EM radiation 1 emitted by a spatially localized EM source. Such a source can be for instance represented by a smart phone or any other wireless device, referred hereafter as Device Under Test (DUT). The object made of a lossy dielectric exposed to non-ionizing electromagnetic radiation under exposure with a constant in time incident power density where lossy means that the dielectric can actually absorb the EM radiation at the frequency of the excitation signal. This ability for EM field absorption is quantitively defined by the value of the imaginary part of the complex dielectric permittivity. Alternatively, it can be defined by the loss tangent (i.e. ratio of the imaginary and real parts of the complex dielectric permittivity).

In case of exposure of a target with a constant in time incident power density 1 as depicted in FIG. 1A, a rapid growth of the temperature, in other words high temperature rise rate as for a given source typical dT/dt threshold can be expressed as a function of the absorbed power density, is observed during the initial time period that may last from several seconds to several minutes. For such exposure durations, the heat spread in the target can be neglected, and the heat distribution is linearly proportional to the absorbed power density. The absolute value of the absorbed power density and/or specific absorption rate (hereafter SAR) can be for instance retrieved using the SAR C⇔T relationship (1) when the duration tends towards 0 s or using a parametric solution of the heat transfer equation for the object under test for longer durations. This phase is referred hereafter as transient (hereafter TR) phase, to be distinguished from the steady-state phase when a relatively small or no further average temperature growth is observed. Note that in the steady-state the distribution of the temperature rise and absorbed power density can be substantially different.

$${\frac{d T}{d t} \vert}_{t = 0} = \frac{1}{c} SAR , \qquad ( 1 )$$

where c is the thermal specific heat of the exposed object.

During the initial time period, the heat spread from the heated zone can be considered as negligible because of a low temperature gradient and relatively long time constant of the heat diffusion. With time, the temperature increases as well as the heat spread from the exposed zone. The heat rate (dT/dt) becomes slower, so the temperature tends to an asymptotic value of T0+ΔT, where T0 is the baseline temperature (e.g., ambient temperature) and ΔT is the steady-state temperature increase. This phase can be referred hereafter as quasi-steady state (hereafter QSS). As soon as the equilibrium condition is achieved with the input power balanced by the thermal loss associated with the heat spread and thermal radiation, no further temperature growth is observed. This condition is commonly referred as the steady state (hereafter SS).

In case of a pulsed excitation by an amplitude-modulated signal 3 as shown in FIG. 1B with a predetermined amplitude Pi and frequency F_{lock}=1/T_{lock}, the TR, QSS, and SS phases can be identified similarly for the average temperature rise as in the case of a non-modulated exposure.

In practice, measurement of the heat dynamics that can be used to retrieve EM metrics, can be substantially complicated by the thermal noise. Measurement of the response signal (i.e., the temperature increase ΔT(t) induced by the absorbed EM power) can be difficult or even impossible if the thermal noise level N(t) is comparable or exceeds the temperature increase in steady state (N≥ΔTmax). Indeed, under this condition the response signal is buried by the thermal noise as in FIG. 1A which makes a bulk response signal.

The present disclosure is using the fact that although the same is also true in case of a modulated excitation signal 3 in FIG. 1B, the response signal can still be retrieved when a steady state SS is reached using the frequency-domain lock-in approach, based on the Fourier transformation theory, as described below.

To illustrate the lock-in approach, let's consider the temperature rise as a sum of the response signal s(t) and noise N(t):

$$Δ T ( t ) = s ( t ) + N ( t ) ; \qquad ( 2 )$$

The response signal s(t) 4 can then be represented as a sum of a “non-periodic” and “periodic” associated with the increase of the average temperature and with the oscillating part, respectively.

In a simplistic aspect, the non-periodic part can be approximated by a function that can be locally approximated by a linear function, while the oscillating part can be represented by a periodic function (e.g., by a sin), leading to the following expression:

$$Δ T ( t ) \approx A ( 1 - {e}^{- Bt} ) + C sin ( {ω}_{0} t ) + N ( t ) . \qquad ( 3 )$$

where A, B, and C are constants selected to fit the thermal dynamics at time instant t, that depends on the thermal properties of the object medium and its formfactor, as well as on the heat source type and power (which are the parameters that define the heat spread from the local heated zone).

Note that in the steady state SS, the first term tends to constant value “A”. It also tends to constant value “A” in the quasi steady-state QSS mode but with a certain degree of accuracy that depends on the relation between the first and the second terms. However, in the transient TR mode, the first term is variable and must be taken into account as it is time dependent and therefore its spectrum is non-zero.

The Fourier transformation applied to the temperature rise signal will give three terms in the spectral domain, corresponding to the exponential (evanescent with frequency) fₑ(ω), periodic (narrowband) fₚ(ω), and noise (broadband) components fₙ(ω) 7:

$$F T ( Δ T ( t ) ) = {f}_{e} ( ω ) + {f}_{p} ( ω ) + {f}_{n} ( ω ) . \qquad ( 4 )$$

FIGS. 1C and 1D illustrate a typical shape of these spectral components in the frequency domain. Thermal noise 7 can be represented by white Gaussian noise. The spectral level of noise (N) is inversely proportional to the square root of the integration time (IT) (i.e., acquisition duration) and sampling frequency (number of measurement points per second) (Fs) and can be estimated as follows:

$$\hat{N} \approx {\int }_{- ∞}^{+ ∞} \vert {f}_{n} ( ω ) \vert df / \sqrt{IT \cdot Fs} . \qquad ( 5 )$$

The periodic term 6 is represented by a narrow spectral component around F_{lock}=ω₀ and expressed as follows:

$${f}_{p} ( ω ) = \frac{Δ {T}_{m o d}}{2} ( δ ( ω - {ω}_{l o c k} ) + δ ( ω + {ω}_{l o c k} ) ) , \qquad ( 6 )$$

where δ is the Dirac delta impulse function, ΔT_{mod} is the amplitude of temperature oscillation at steady state in FIG. 1B. Its position along frequency axis can be controlled through the amplitude modulation of the absorbed power density.

Finally, the exponential term 5, is a wide evanescent spectral component that can partially overlap the narrow F_{lock} spectral component related to the response periodic signal. The width and amplitude of the wide component are defined by the Fourier transform of the exponential term given as follows:

$${f}_{e} ( ω ) = Δ T ( π δ ( f ) + \frac{1}{j 2 π f} - \frac{1}{B + j 2 π f} ) , \qquad ( 7 )$$

In FIGS. 1C and 1D, the narrow spectral component at F_{lock} 6 corresponds to the periodic amplitude modulation signal with amplitude ΔT_{mod}/2 and remains the same in both regimes. On the contrary, the bandwidths of the spectral component related to the average rise of temperature are different in the transient and steady state regimes. In the steady state regime of FIG. 1D, the spectrum 51 of the average temperature rise component is narrowband and centred around the zero frequency and thus can be easily filtered. In the transient mode in FIG. 1C, the spectrum 5 of the average temperature rise component is wider leading to an overlap between the narrow spectral component related to the amplitude-modulated signal at F_{lock} that complicates distinguishing these two spectral components. This overlapping introduces errors on the retrieval of the absolute value of the temperature rise (ΔT_{mod}), hence the absorbed power density or SAR. This explains why the steady state condition is used in the lock-in technique.

Hereafter, we refer to the spectrum that corresponds to the average temperature rise as parasitic spectrum.

To retrieve the absorbed power density or specific absorption rate, hereafter SAR, from the measured temperature dynamics, the following steps and conditions are to be fulfilled:
a. The excitation signal is modulated in time at frequency F_{lock},
b. The Fourier transform of the acquired temperature signal is calculated (i.e., FT{ΔT(t)}),
c. Bandpass filter is applied at F_{lock} to filter the spectrum of the exponential term (fₑ(ω)) and ambient noise (fₙ(ω)) from the response signal (fₚ(ω)),
d. applying an inverse Fourier transformation to fₚ(ω) the useful signal to determine the temperature rise,
e. Calculating the power density or SAR using said temperature rise.

We define the following two figures of merit SNR and SPR referring to signal to noise ratio and signal to parasitic spectrum (e.g., spectrum of exponential rise of temperature) ratio. The first quantifies the difference between the amplitude of temperature oscillation and noise, whereas the second describes how fₚ(ω) overlaps with the fₑ(ω):

$$S N R = \frac{Δ {T}_{m o d}}{N} \qquad ( 8. a )$$

$$SPR = \frac{{f}_{p} ( ω )}{{f}_{e} ( ω )} \qquad ( 8. b )$$

Conventional lock-in method is implemented at steady-state where the spectral image of the heat dynamics corresponds to a superposition of the quasi-static part represented by a narrow band spectrum 51 around F=0 Hz and periodic part with a frequency F=F_{lock} 6, respectively as in FIG. 1D. The parasitic spectrum related to average rise of temperature and the thermal noise are then removed by filtering of F_{lock}. The spectrum at F_{lock} equals only to fₚ(F_{lock}), i.e., ΔT_{mod}/2 (6), which is related to power density or SAR as given in (1).

In the transient state, lock-in thermography becomes less efficient as the heat dynamics is represented by the superposition of the continuous increase of temperature with a periodic variation, which results in a broadband spectrum (fₑ(ω)) 5 around 0 Hz that overlaps with the narrowband spectrum of the useful signal (fₚ(ω)) 6 at F=F_{lock} as in FIG. 1C. Thus, it is difficult to distinguish between the spectrum corresponding to the periodic part of the excitation signal and the one corresponding to the average temperature rise. Unlike steady state where the spectrum at F_{lock} equals to fₚ(F_{lock}), in transient state it equals to the sum of fₚ(F_{lock}) and fₑ(F_{lock}).

This aliasing between fₚ(ω) and fₑ(ω) introduces errors in the retrieved power density, 2-dimensional (2D) distribution and absolute value. This makes difficult to use of lock-in thermography in transient state to retrieve power density.

An idea would be to shift the useful spectrum fₚ(ω) towards higher frequencies by increasing F_{lock} in order to mitigate its overlapping with fₑ(F_{lock}), hence increase the SPR. However, increasing F_{lock} implies reduction of exposure duration at each lock-in period, thus it reduces the amplitude of temperature oscillations (ΔT_{mod}), which finally results in drastic decrease of the SNR (ΔT_{mod}/N) and does not solve the problem.

To improve the efficiency of the lock-in technique in transient phase, i.e. use of lock-in in transient phase to speed up measurements while guarantying a sufficiently high SPR and SNR that allows an accurate retrieval of power density, the present disclosure proposes the transient lock-in solution which comprises two main types of processes:
Reconstructing fₑ(ω) separately from fₚ(ω) using adapted signals as in aspect 1 and aspect 2 or
an advanced post processing technique as in aspect 3 hereunder. Then if fₑ(ω) is known, fₚ(ω) can be distinguished from the superposition of fₚ(ω) and fₑ(ω).

In addition, to obtain the periodic response signal in the time domain, Reshaping of fₑ(ω) in the frequency domain is done in such a way that the ratio fₚ(F_{lock})/fₑ(F_{lock}) is as small as possible (depending on the constraints of the SPR).

In consequence, a basis of the present disclosure transient lock-in method consists in either filtering the wideband parasite spectrum present in the transient regime or in reshaping it to mitigate its aliasing with the useful signal. Some of these aspects can be combined to have a better efficiency in terms of speedup and/or accuracy. This allows one to use lock-in in transient phase to accurately retrieve the EM power density thanks to filtering techniques used to remove the ambient noise and parasitic spectrum related to the average increase of temperature.

We present hereafter different aspects of the proposed transient lock-in technique that allows to measure low-amplitude signals buried in the noise (by improving SNR), minimizing the impact of the heat spread (by improving SPR), while simultaneously reducing the exposure duration (use of transient phase). Additionally, this allows to remove the sources of uncertainties related to the heat spread from the DUT to the object under test by heat conduction or convection, environmental temperature drift, and variations of received RF signal level.

To summarize, the method of the present disclosure comprises first a method for retrieving a useful signal 8 as shown in FIG. 1E from a bulk response signal 4 as in FIG. 1B emitted by a target subjected to an excitation signal 3, comprising:
a.—providing a first excitation signal 3a, 3b, 3c at least modulated at a frequency F_{lock} during a first period of time corresponding to a transient mode of a response signal causing a first bulk response signal 4a, 4b, 4c and recording said first bulk response signal,
b.—calculating a first Fourier transform FT{ΔT(t)} 10a, 10b, 10c of said bulk response signal in response to said first excitation signal during said first period to provide a first spectrum of an exponential term (fₑ(ω)) 5a, 5b, 5c, a first spectrum of ambient noise (fₙ(ω)) 7 and a first spectrum of a useful signal (fₚ(ω)) 6a, 6b, 6c in said first measured bulk response signal,
c.—extracting said first spectrum of a useful signal (fₚ(ω)) 6a, 6b, 6c through removing said first spectrum of the exponential term (fₑ(ω)) 5a, 5b, 5c from said first Fourier transform.

In addition to the process, a step of filtering the ambient noise may be done.

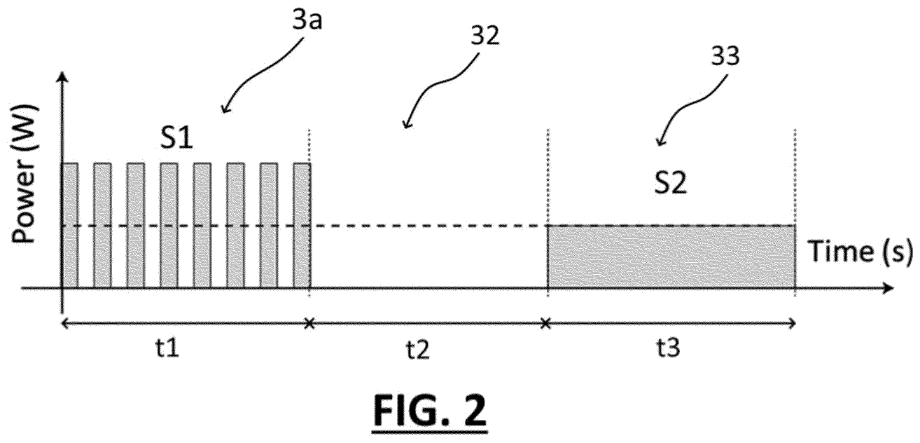

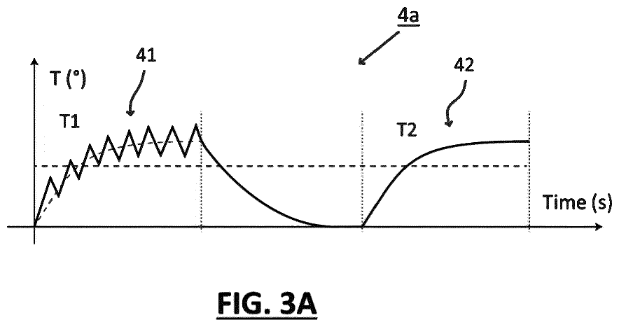

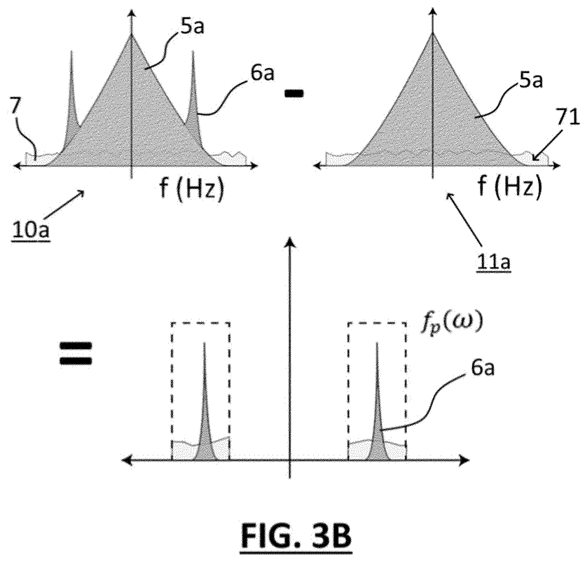

A first aspect makes use of a specific excitation signal 3a that consist of a sequence of a first sub-signal S1 3 made of a periodic modulated wave at F_{loack1} during t1 and a non-modulated (F_{lock2}=0 Hz) sub-signal S2 33 during t3 separated by a zero signal 32 during t2. The spectrum of the recorded temperature at F_{lock2}=0 Hz is used to de-embed the quasi-exponential part of the temperature rise resulting from measurement at a non-zero lock-in frequency (i.e., periodic signal at F_{lock1}). The averaged power of the periodic signal should be equal to one of signal at F_{lock2}=0 Hz at every period T_{lock}. This aspect allows to use efficiently lock-in at transient state, thus reducing measurement time, and benefit from the advantages of lock-in in steady state, i.e., improvement of SNR compared to measurement from continuous-wave signal. An example of such aspect is given in FIG. 2 and FIGS. 3A and 3B, transient lock-in is implemented employing a specific input power waveform consisting of two sub signals S1 and S2 as described in FIG. 2. S1 is periodic with a period T_{lock}, amplitude ΔP₁, offset

$${P}_{1}^{D C} ,$$

and duration t1. S2 is continuous with magnitude

$${P}_{2}^{D C}$$

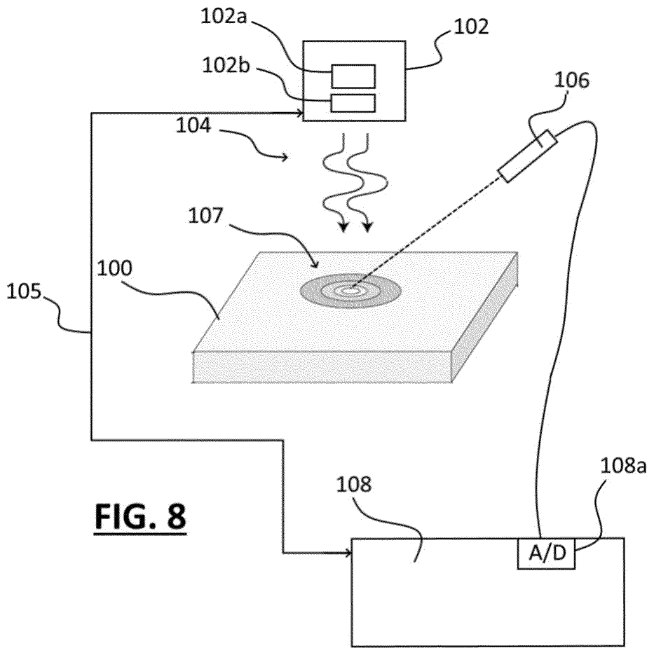

and duration t3. The power generator 102 is switched off for duration t2 to allow the cooling of the exposed object (e.g., screen, human skin equivalent model, etc. 100—as exemplified in FIG. 8. The curves T1 41 and T2 42 are temperature rise curves resulting from said sub-signals S1 and S2, respectively. In FIG. 3B, the useful spectral component fₚ(F_{lock}) 6a is de-embedded from the spectrum of T1 10a by subtracting the spectrum of T2 11a from the spectrum of T1 10a. This is feasible if the following conditions are satisfied:

$${\int }_{{T}_{l o c k}} {S}_{1} ( t ) d t \approx Y {\int }_{{T}_{l o c k}} {S}_{2} ( t ) dt , i . e , {P}_{1}^{D C} \approx Y {P}_{2}^{D C} \qquad ( 9. a )$$

$$and$$

$${t}_{1} \approx {t}_{2} \qquad ( 9. b )$$

where γ is a linear coefficient (γ<0). Furthermore, ΔP₁ is up bounded by the maximum input signal power.

In this aspect, lock-in is performed in the transient state thanks to the proposed method that allows to filter the parasitic spectrum related to the averaged exponential increase of the temperature signal (i.e., fₑ(ω)) and consequently retrieve the useful signal (fₚ(ω)). In this aspect, the acquisition time is significantly reduced compared to conventional lock-in applied in steady-state where the thermal equilibrium should be reached. Furthermore, the SNR and SPR are significantly improved compared to measurement technique using periodic excitation with such a method and are improved by at least a factor of 2 compared to measurement conventional lock-in such as periodic excitation.

To summarize, in this aspect, said first excitation signal 3a is followed with a further signal in a second period of time t2, t3, and the method comprises:
providing said second period of time with a first sub-period of time t2 where said further signal comprises a null excitation signal 32 value to let said bulk response signal return to ambient (meaning that the temperature of the target has returned to the level of the temperature at the beginning of the first time interval) and a second sub period of time t3 where said further signal comprises a constant power excitation signal 33 having a power value equal to the mean power of said first signal during said first period,
calculating a second Fourier transform FT{ΔT(t)} 11a of a second measured bulk response signal in response to said constant power excitation signal in said second sub-period to provide a second spectrum of said exponential term (fₑ(ω)) 5a, a second spectrum of ambient noise (fₙ(ω)) 71 in said second measured bulk response signal,
subtracting said second spectrum of said exponential term (fₑ(ω)) 5a, from said first spectrum of said exponential term (fₑ(ω)) 5a) in said first Fourier transform FT{ΔT(t)} for removing said first spectrum of the exponential term (fₑ(ω)) 5a from said first Fourier transform and extracting the first spectrum of the useful signal (fₚ(ω)) 6a.

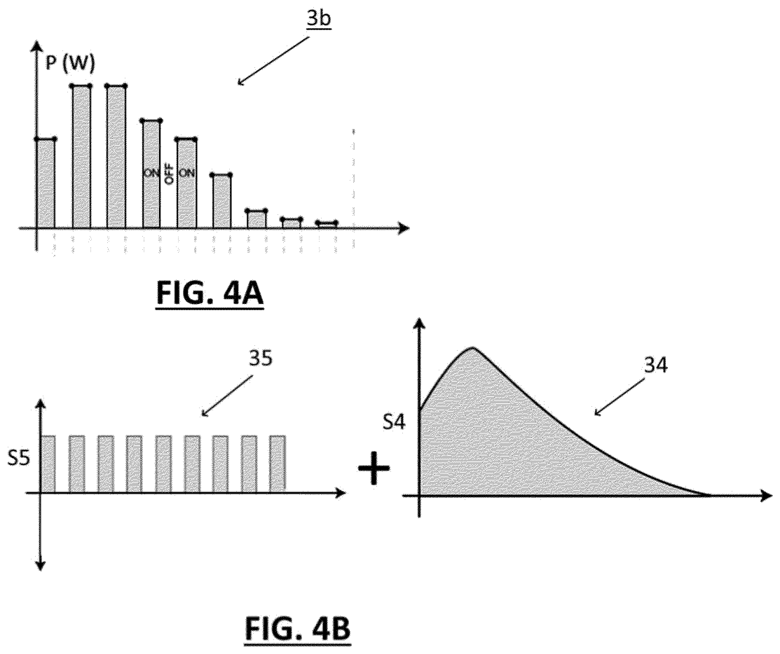

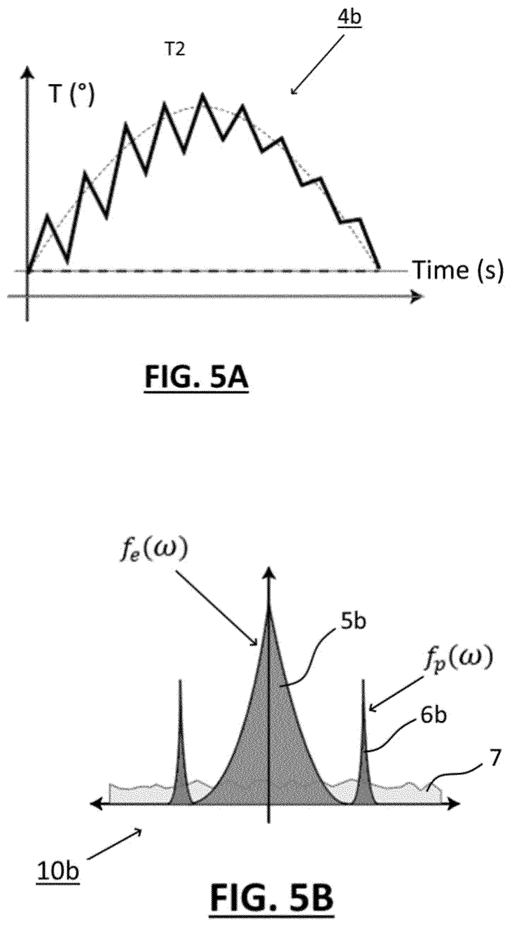

A second aspect depicted in FIG. 4A uses an excitation signal 3b combining a periodic excitation signal power modulated at frequency F_{lock} 35 and a specific non-periodic signal 34 shown in FIG. 4B to provide the excitation signal of FIG. 4A. The non-periodic signal 34 results in a narrow band spectrum having low spectral component at F_{lock}, thus, it doesn't overlap with the beneficial spectral component at F_{lock}. This aspect allows to use efficiently lock-in at transient state, thus reducing measurement time, and benefit from the advantages of lock-in in steady state. The superposed periodic signal S5 35 and non-periodic signal S4 34 needs to have the particularity that the amplitude of its spectrum at F_{lock} should be as low as possible compared to spectral component S5 (e.g., fₚ(F_{lock})/fₑ(F_{lock})<0.1 depending on the acceptable accuracy). Then the resulting bulk signal 4b represented in FIG. 5A is such that the non-periodic signal spectrum 5b in FIG. 5B after the Fourier transform does not recover part of the useful spectrum fₚ(F_{lock}) 6b allowing to retrieve such useful spectrum and signal applying a bandpass filter at F_{lock}.

In the given example, the non-periodic part of the excitation signal is modulated so that the temperature 4b takes a Gaussian like shape with time in FIG. 5A. Here, the larger the width of the Gaussian curve in time is, the narrower its spectrum would be and, consequently, the lower the overlapping between fₚ(ω) and fₑ(ω) at F_{lock}.

To summarize, in this aspect, the method comprises:
modulating said first excitation signal 35 with a non-periodic envelope 34 during said first period of time wherein said non-periodic envelope 34 comprises a positive skew distribution during said first period of time, said positive skew distribution being adapted to have said bulk signal comprising a non-periodic gaussian shape 4b in order that said first spectrum of said exponential term (fₑ(ω)) 5b does not overlap said third spectrum of said useful signal (fₚ(ω)) 6b, and
filtering said first spectrum of said exponential term (fₑ(ω)) 5b in said first Fourier transform for removing said first spectrum of the exponential term (fₑ(ω)) from said first Fourier transform and extracting the first spectrum of the useful signal (fₚ(ω)) 6b.

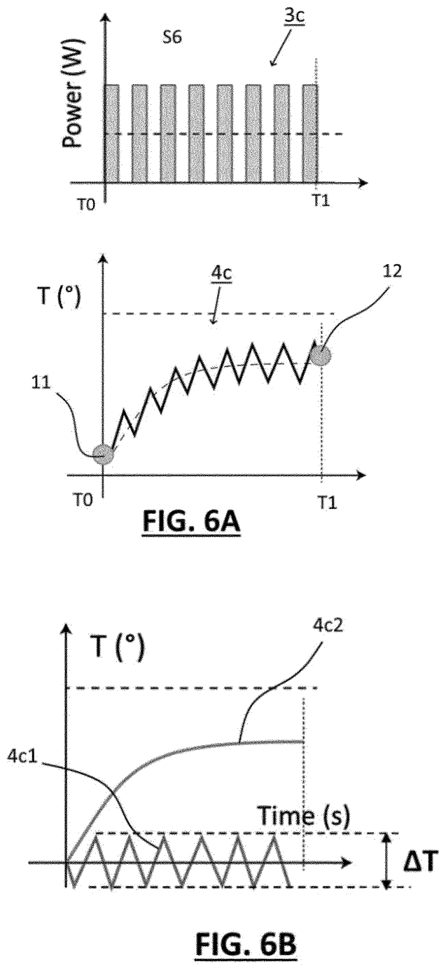

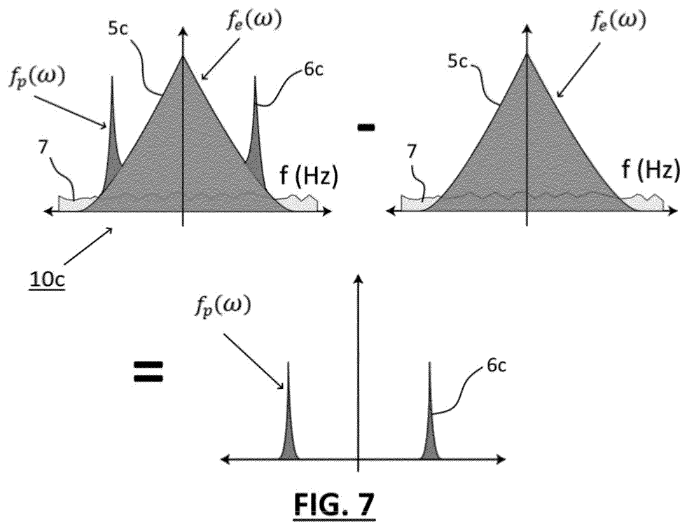

A third aspect uses an excitation signal S6 3c that may be similar than signal S1 in the first aspect but uses an interpolation over the time interval [T1−T0] with starting temperature value 11 at T0 and temperature value 12 at T1 as shown in FIG. 6B to reconstruct the temperature rise 4c2 from the static part 4cl of the excitation signal S6, or in other words, interpolation is made to reconstruct the quasi-exponential part of the temperature rise 4c2 having a spectrum 5c corresponding to the broadband noise spectrum of the signal T2 generated from its quasi-exponential part 4c2. Therefore, in the spectrum of T2, fₚ(ω) is de-embedded from fₚ(ω) by subtracting the spectrum of curve 4c2 from the one of curve 4c.

This aspect presents the same advantages as the first aspect: use of lock-in thermography in transient state resulting in reduction of acquisition time and SNR improvement, compared to measurement with constant power excitation.

This technique allows to apply efficiently lock-in at transient state and thus reducing measurement time compared to conventional lock-in applied in steady-state. Furthermore, the SPR is significantly improved compared to measurement using periodic excitation (in the presented example in annex 1, SPR is improved with a factor of 3.5 compared to measurement conventional lock-in, i.e., periodic excitation).

In this method is implemented
a. a reconstruction by interpolation of a non-periodic part of the bulk response signal 4c after provision of said first excitation signal 3c power modulated at a frequency F_{lock} during a first period of time corresponding to a transient mode of said bulk response signal,
b. a calculation of a third Fourier transform FT{ΔT(t)} of said non-periodic part to provide a third spectrum of an exponential term (fₑ(ω)) 5c,
c. a subtraction of said third spectrum of said exponential term (fₑ(ω)) from said first spectrum of said exponential term (fₑ(ω)), said spectrum of a useful signal (fₚ(ω)) 6c and said first spectrum of ambient noise (fₙ(ω)) 7 in said first Fourier transform FT{ΔT(t)} for removing said first spectrum of the exponential term (fₑ(ω)) 5c from said first Fourier transform and extracting the first spectrum of the useful signal (fₚ(ω)) 6c.

In the present disclosure, filtering the ambient noise (fₙ(ω)) 7 may be done after extracting the useful signal or before in the time domain or in the frequency domain as known in the art.

FIG. 8 shows a schematic view of an implementation system for the method disclosed, such system comprising:
a target 100 which may be a 3D structure comprising at least one layer of a dielectric medium made of an organic or inorganic insulating material or semiconductor material, such target providing a bulk response signal 107 when subjected to an excitation signal 104 such as an electromagnetic or thermal excitation signal;
an emitting device 102 source of the excitation signal 104 and in said source means 102a to modulate a power of said excitation signal at a frequency F_{lock} and means 102b to modulate a power of said excitation signal with a non-periodic envelope. Said emitting device source of excitation signal may be for example a wireless communication device but may also be any device emitting an excitation signal such as microwave, mm-wave, IR or visible light generated by an electromagnetic source such as an EM power generator, a lamp, a laser or a heater. The excitation signal may also be a heat wave generated by a heat source driven by an electrical or mechanical force;
sensor means 106 for acquiring said bulk response signal;
analog to digital conversion means 108a connected to said sensor and computer means 108b configured to process said recording, reconstructing, calculating, and subtracting on digital data representative of bulk response signals converted by said analog to digital conversion means 108a and implementing the disclosed method. In the disclosed example, said target 100 is a test object subject to EM radiation of said wireless communication device 102, said sensor 106 is an IR sensor measuring intensity the IR radiation emitted by the target in response to the heat induced in said target subject to said EM radiation.

The system may also comprise communication means 105 between said source of excitation signal and said computer means for scheduling emission of said excitation signal and acquiring said bulk response signal.

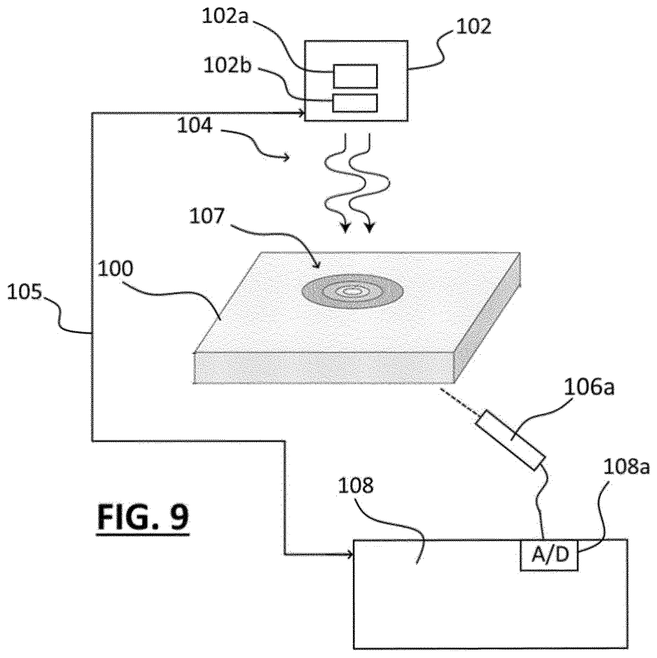

FIG. 9 is an alternative design where a sensor 106a is located under the target and receives IR radiation emitted from the back side of the target. Such aspect is the preferred aspect related to the EM dosimetry where the response signal 107 is generated from the bottom surface of the target (i.e. opposite to the source position).

In other realization modes, the bulk response signal 107 is a time-variable physical quantity relative to the heat generated in the medium of the target when exposed to said excitation signal such as:
an intensity of an IR radiation generated by said medium in response to said excitation signal, or
an amplitude and/or frequency variation of an emitted or reflected EM radiation (e.g. visible light) by a material of the target such as a thermosensitive material, such as liquid crystal or a phase change material such as chalcogenide glass or vanadium dioxide in response to said excitation signal; or
a voltage generated by a thermocouple attached or embedded in said medium of the target.

According to the disclosure a feature and advantage of the method is to stop emission of said excitation signal before a thermal steady state condition of the target is reached which is a novel method since in the prior art such steady state was awaited before starting the lock in method.

### INDUSTRIAL APPLICATION

The proposed transient lock-in method can offer a great advantage for an hybrid EM/thermal dosimetry or characterization methods applied to various applications and, in particular, to the user exposure compliance testing of 5G/6G wireless devices operating at frequencies above 6 GHz. Other applications are possible in measurements where a power source is used to expose a target and where the signal/noise ratio is low, including EM metrology for characterization of the antenna radiation characteristics and non-invasive material testing for possible defects, such as discontinuity of the target medium or inclusions of other media characterized by different EM and/or thermal properties.

What is claimed is:

1. A method for retrieving a useful signal from a bulk response signal emitted by a target subjected to an excitation signal, comprising:
providing a first excitation signal at least modulated at a frequency Flock during a first period of time corresponding to a transient mode of a response signal and causing a first bulk response signal and recording said first bulk response signal,
calculating a first Fourier transform of said bulk response signal in response to said first excitation signal during said first period to provide a first spectrum of an exponential term a first spectrum of ambient noise and a first spectrum of a useful signal in said first measured bulk response signal,
extracting said first spectrum of a useful signal through removing said first spectrum of the exponential term from said first Fourier transform.

2. The method according to claim 1 wherein said first excitation signal is followed with a further signal in a second period of time, said method comprising further:
providing said second period of time with a first sub-period of time where said further signal comprises a null excitation signal value to let said bulk response signal end and a second sub period of time where said further signal comprises a constant power excitation signal having a power value equal to the mean power of said first signal during said first period,
calculating a second Fourier transform of a second measured bulk response signal in response to said constant power excitation signal in said second sub-period to provide a second spectrum of said exponential term, in said second measured bulk response signal,
subtracting said second spectrum of said exponential term from said first spectrum of said exponential term in said first Fourier transform for removing said first spectrum of the exponential term from said first Fourier transform and extracting the first spectrum of the useful signal.

3. The method according to claim 1 comprising further:
modulating said first excitation signal with a non-periodic envelope during said first period of time wherein said non-periodic envelope comprises a positive skew distribution during said first period of time, said positive skew distribution being adapted to have said bulk signal comprising a non-periodic Gaussian-like shape in order that said first spectrum of said exponential term does not overlap said third spectrum of said useful signal, and
filtering said first spectrum of said exponential term in said first Fourier transform for removing said first spectrum of the exponential term from said first Fourier transform and extracting the first spectrum of the useful signal.

4. The method according to claim 1, comprising:
reconstructing by interpolation of a non-periodic part of the bulk response signal after provision of said first excitation signal modulated at a frequency F_{lock} during a first period of time corresponding to a transient mode of said bulk response signal,
calculating a third Fourier transform of said non-periodic part to provide a third spectrum of an exponential term,
subtracting said third spectrum of said exponential term from said first spectrum of said exponential term, said spectrum of a useful signal in said first Fourier transform for removing said first spectrum of the exponential term from said first Fourier transform and extracting the first spectrum of the useful signal.

5. The method according to claim 1 comprising an inverse Fourier transform to provide said useful signal after extracting the first spectrum of the useful signal.

6. The method according to claim 5 comprising a retrieval of a quantitative characteristic of the EM field incident on or absorbed by the target based on said useful signal and said first excitation signal.

7. The method according claim 1 wherein said excitation signal is one of electromagnetic waves such as microwave, mm-wave, IR, visible, or UV light generated by an electromagnetic source such as a wireless communication device, an EM power generator, a lamp, a laser or a heater or their combination.

8. The method according to claim 1 wherein said excitation signal is a heat wave generated by a heat source driven by an electrical or mechanical force.

9. The method according to claim 1 wherein said bulk response signal is a time-variable physical quantity relative to the heat generated by a medium of the target when exposed to said excitation signal such as:
an intensity of an IR radiation generated by said medium in response to said excitation signal, or
an amplitude and/or frequency variation of an emitted or reflected light by a material of the target such as a thermosensitive material, such as liquid crystal or a phase change material including chalcogenide glass or vanadium dioxide in response to said excitation signal; or
a voltage generated by a thermocouple attached or embedded in said medium of the target.

10. The method according to claim 1 wherein emission of said excitation signal is stopped before a thermal steady state condition of the target is reached.

11. The method according to claim 1 comprising filtering the ambient noise in the time or frequency domain to suppress the ambient noise from to useful signal.

12. A system for performing the method of claim 1 comprising a source of excitation signal, in said source means to modulate a power of said excitation signal at a frequency Flock, a target providing a bulk response signal when subjected to said excitation signal, sensor means for acquiring said bulk response signal, analog to digital conversion means and computer means configured to process said recording, reconstructing, calculating and subtracting on digital data representative of bulk response signals converted by said analog to digital conversion means.

13. The system according to claim 12 wherein said source comprises means 102b to modulate a power of said excitation signal with a non-periodic envelope.

14. The system according to claim 12 wherein said target has a 3D structure comprising at least one layer of a dielectric medium made of an organic or inorganic insulating material or semiconductor material.

15. The system according to claim 12 wherein said source of excitation signal is a wireless communication device and said target is a test object subject to EM radiation of said wireless communication device, said sensor is an IR sensor measuring intensity of the IR radiation, which is proportional to the temperature of the object being a source of this radiation.

16. The system according to claim 12 comprising further communication means between said source of excitation signal and said computer means for scheduling emission of said excitation signal and acquiring said bulk response signal.
